(19) United States
(12) Patent Application Publication
(10) Pub. No.: US 2026/0182282 A1
(43) Pub. Date: Jun. 25, 2026

(54) ETCHING LIQUID, ETCHING METHOD, AND METHOD FOR MANUFACTURING SEMICONDUCTOR DEVICE

(71) Applicant: Mitsubishi Chemical Corporation, Tokyo (JP)

(72) Inventors: Haru SENDO, Chiyoda-ku (JP); Tetsuo KASAI, Chiyoda-ku (JP); Hiroyuki SHIRAE, Chiyoda-ku (JP)

(73) Assignee: Mitsubishi Chemical Corporation, Tokyo (JP)

(21) Appl. No.: 19/432,700

(22) Filed: Dec. 24, 2025

Related U.S. Application Data
(63) Continuation of application No. PCT/JP2024/023438, filed on Jun. 27, 2024.

(30) Foreign Application Priority Data
Jun. 28, 2023 (JP) 2023-105663
Jun. 28, 2023 (JP) 2023-105664

(51) Int. Cl. H10P 50/28; H10P 50/24

(52) U.S. Cl. CPC H10P 50/283; H10P 50/242

(57) ABSTRACT

The present disclosure relates to an etching liquid comprising: an alkaline compound (A); and at least one compound (B) selected from the group consisting of a thiol compound (B1) and a nonionic surfactant (B2) represented by Formula (1) below, wherein ER₁₁₀/ER₁₀₀≥0.5, where ER₁₁₀ is an etching rate of a (110) plane of a silicon crystal, and ER₁₀₀ is an etching rate of a (100) plane of the silicon crystal, R¹XO—(CₘH₂ₘO)ₙ—R² (1), where R¹ is an alkyl group having 7 or more carbons, R² is a hydrogen atom or an alkyl group, X is a single bond or a phenylene group, m is an integer of 1 to 6, and n is from 4 to 25.

### CROSS-REFERENCE TO RELATED APPLICATIONS

This application is a continuation of International Application PCT/JP2024/023438 filed on Jun. 27, 2024, and claims priority to Japanese application No. 2023-105663 filed on Jun. 28, 2023 and Japanese application No. 2023-105664 filed on Jun. 28, 2023 the disclosures of all of which are incorporated herein by reference in their entireties.

### TECHNICAL FIELD

The present disclosure relates to an etching liquid, an etching method, and a method for manufacturing a semiconductor device.

### BACKGROUND ART

Integrated circuits have been progressively scaled to finer geometries in accordance with Moore's law.

In recent years, studies have been conducted not only to reduce the size of typical planar transistors but also to promote further scaling to finer geometries and higher integration by changing a planar structure to a three-dimensional structure to improve performance as in Fin-type transistors (FinFETs) and gate-all-around transistors (GAAFETs). As a transistor structure that can be expected to achieve further scaling to finer geometries, vertical transistors (VFETs) are being studied. VFETs have even finer geometries and can have improved performance through a structural change from typical planar transistors to vertical structures.

In GAAFETs, nanosheet and/or nanowire-shaped channels are covered with gate electrodes to increase contact area between the channel and the gate electrode, thereby improving transistor performance per unit area.

VFETs have a structure with nanosheet and/or nanowire-shaped channels stacked in the vertical direction and a smaller standard cell layout area than those of planar transistors (HFETs), thereby improving transistor performance per unit area.

Forming GAAFETs or VFETs requires an etching liquid that dissolves silicon in the etching process. As an etching liquid that dissolves silicon, for example, Patent Literatures 1 and 2 disclose an etching liquid containing an alkaline compound.

### CITATION LIST

### Patent Literature

Patent Literature 1: JP 2017-108122 A
Patent Literature 2: JP 2021-136429 A

### SUMMARY

### Technical Problem

However, the etching liquids disclosed in Patent Literatures 1 and 2 have poor selective dissolution of the (110) plane of silicon crystal relative to the (100) plane of the silicon crystal.

In recent years, scaling to finer geometries has particularly been strongly demanded for FETs, requiring control of orientation-dependent etching of silicon between gaps as narrow as several tens of nanometers. In FETs having a structure formed perpendicular to the (100) plane of a silicon crystal, a nano-shape needs to be formed by etching from the horizontal direction, thus requiring an etching liquid with excellent selective dissolution of the (110) plane of the silicon crystal. In particular, the selective dissolution of each plane orientation is not easy to control because the surface is composed of the same element.

The present disclosure has been made in view of such problems, and an object of the present disclosure is to provide an etching liquid having excellent selective dissolution of the (110) plane of a silicon crystal relative to the (100) plane of the silicon crystal.

Another object of the present disclosure is to provide an etching method, a method for manufacturing a semiconductor device, a method for manufacturing a vertical transistor, and a method for manufacturing a gate-all-around transistor, using the etching liquid.

### Solution to Problem

The present disclosure has been made in view of such problems, and an object of the present disclosure is to provide an etching liquid having excellent selective dissolution of the (110) plane of a silicon crystal relative to the (100) plane of the silicon crystal.

Another object of the present disclosure is to provide an etching method, a method for manufacturing a semiconductor device, a method for manufacturing a vertical transistor, and a method for manufacturing a gate-all-around transistor, using the etching liquid.
[1] An etching liquid containing:
an alkaline compound (A); and
at least one compound (B) selected from the group consisting of a thiol compound (B1) and a nonionic surfactant (B2) represented by Formula (1) below,
in which ER₁₁₀/ER₁₀₀≥0.5, where ER₁₁₀ is an etching rate of a (110) plane of a silicon crystal, and ER₁₀₀ is an etching rate of a (100) plane of the silicon crystal,

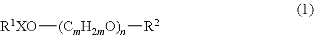

where R¹ is an alkyl group having 7 or more carbons, R² is a hydrogen atom or an alkyl group, X is a single bond or a phenylene group, m is an integer of 1 to 6, and n is from 4 to 25.
[2] The etching liquid according to [1], in which the alkaline compound (A) includes at least one compound selected from the group consisting of a quaternary ammonium hydroxide compound, potassium hydroxide, and calcium hydroxide.
[3] The etching liquid according to [1] or [2], in which the thiol compound (B1) includes a compound containing a hydrocarbon group and a thiol group.
[4] The etching liquid according to any of [1] to [3], in which the thiol compound (B1) includes at least one compound selected from the group consisting of thioglycerol, thioglycolic acid, ethanolamine thioglycolate, 8-mercaptooctanoic acid, 1-octanethiol, 1-undecanethiol, 1-dodecanethiol, 11-mercapto-1-undecanol, 11-mercaptoundecanoic acid, 16-mercaptohexadecanoic acid, 4,4′-dithiodibutyric acid, bis(2-hydroxyethyl) disulfide, and didodecane disulfide.
[5] The etching liquid according to any of [1] to [4], in which X in Formula (1) is a phenylene group.
[6] The etching liquid according to any of [1] to [5], further containing water.
[7] The etching liquid according to [6], in which a content of water in 100 mass % of the etching liquid is 60 mass % or more.
[8] The etching liquid according to any of [1] to [7], in which a content of the compound (B) in 100 mass % of the etching liquid is from 0.1 mass % to 39.99 mass %.
[9] The etching liquid according to any of [1] to [8], in which a content of the compound (B) in 100 mass % of the etching liquid is from 0.01 mass % to 5 mass %.
[10] The etching liquid according to any of [1] to [9], in which a mass of the thiol compound (B1) relative to a mass of the alkaline compound (A) is from 0.001 to 2.
[11] The etching liquid according to any of [1] to [10] for use as an etching liquid for silicon dissolution.
[12] The etching liquid according to any of [1] to [11], in which the etching liquid dissolves the (110) plane of the silicon crystal relative to the (100) plane of the silicon crystal.
[13] The etching liquid according to any of [1] to [12], in which the silicon is single crystal silicon.
[14] An etching method for etching a structure containing silicon using the etching liquid described in any of [1] to [13].
[15] A method for manufacturing a semiconductor device, the method including etching a structure containing silicon using the etching liquid described in any of [1] to [13].
[16] A method for manufacturing a vertical transistor, the method including etching a structure containing silicon using the etching liquid described in any of [1] to [13].
[17] A method for manufacturing a gate-all-around transistor, the method including etching a structure containing silicon using the etching liquid described in any of [1] to [13].
[18] A method for etching a structure containing silicon, the method including selectively etching a (110) plane of a silicon crystal relative to a (100) plane of the silicon crystal using an etching liquid containing an alkaline compound (A) and at least one compound (B) selected from the group consisting of a thiol compound (B1) and a nonionic surfactant (B2) represented by Formula (2) below:

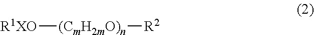

where R¹ is an alkyl group having 1 or more carbons, R² is a hydrogen atom or an alkyl group, X is a single bond or a phenylene group, m is an integer of 1 to 6, and n is from 4 to 25.
[19] A method for manufacturing a semiconductor device, the method including selectively etching a (110) plane of a silicon crystal relative to a (100) plane of the silicon crystal using an etching liquid containing an alkaline compound (A) and at least one compound (B) selected from the group consisting of a thiol compound (B1) and a nonionic surfactant (B2) represented by Formula (2) below:

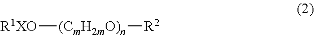

where R¹ is an alkyl group having 1 or more carbons, R² is a hydrogen atom or an alkyl group, X is a single bond or a phenylene group, m is an integer of 1 to 6, and n is from 4 to 25.

### Advantageous Effects

The etching liquid of the present disclosure has excellent selective dissolution of the (110) plane of a silicon crystal relative to the (100) plane of the silicon crystal.

The etching method of the present disclosure, the method for manufacturing a semiconductor device of the present disclosure, the method for manufacturing a vertical transistor of the present disclosure, and the method for manufacturing a gate-all-around transistor of the present disclosure have excellent selective dissolution of the (110) plane of a silicon crystal relative to the (100) plane of the silicon crystal in the etching process, thereby enabling high-precision etching and high-yield manufacture of a desired product.

### DESCRIPTION OF EMBODIMENTS

Hereinafter, the present disclosure will be described in detail, but the present disclosure is not limited to the following embodiments and can be implemented with various modifications within the scope of the gist of the present disclosure. In the present specification, a numerical range expressed using “to” means that the numerical values or physical property values before and after “to” are included in the numerical range.

An etching liquid of the present disclosure contains an alkaline compound (A) (which may hereinafter be referred to as “the component (A)”) and at least one compound (B) (which may hereinafter be referred to as “the component (B)”) selected from the group consisting of a thiol compound (B1) (which may hereinafter be referred to as “the component (B1)”) and a nonionic surfactant (B2) (which may hereinafter be referred to as “the component (B2)”) represented by Formula (1) below, thereby having excellent selective dissolution of the (110) plane of a silicon crystal relative to the (100) plane of the silicon crystal. The etching liquid of the present disclosure preferably further contains water (which may hereinafter be referred to as “the component (C)”).

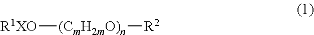

where R¹ is an alkyl group having 7 or more carbons, R² is a hydrogen atom or an alkyl group, X is a single bond or a phenylene group, m is an integer of 1 to 6, and n is from 4 to 25.

The reason for the excellent selective dissolution of the (110) plane of a silicon crystal provided by the etching liquid of the present disclosure relative to the (100) plane of the silicon crystal is considered as follows.

When a silicon crystal is etched using the etching liquid of the present disclosure, the component (A) dissolves silicon, and the component (B) adsorbs and protects Si^{δ+} on the surface of the silicon crystal through covalent bonding. The adsorption protection for the surface of the silicon crystal by the component (B) is more pronounced on the (100) plane than on the (110) plane. It is considered that, as a result, the etching liquid of the present disclosure has excellent selective dissolution of the (110) plane of a silicon crystal relative to the (100) plane of the silicon crystal.

### Component (A)

The component (A) is an alkaline compound (A). The etching liquid of the present disclosure contains the alkaline compound (A), thereby having excellent dissolution of silicon.

Examples of the component (A) include organic alkali compounds, such as quaternary ammonium hydroxide compounds (e.g., tetramethylammonium hydroxide, tetraethylammonium hydroxide, and tetrabutylammonium hydroxide); and inorganic alkali compounds, such as metal hydroxides (e.g., sodium hydroxide, potassium hydroxide, and calcium hydroxide). One of these components (A) may be used alone, or two or more may be used in combination. Among these components (A), because of the low content of sodium, which is likely to affect transistor performance, the component (A) is preferably a quaternary ammonium hydroxide compound, potassium hydroxide, or calcium hydroxide, preferably a quaternary ammonium hydroxide compound, and preferably tetramethylammonium hydroxide or tetrabutylammonium hydroxide.

In the perspective of the excellent dissolution of silicon, the content of the component (A) in 100 mass % of the etching liquid is preferably 0.1 mass % or more, preferably 0.2 mass % or more, and preferably 0.5 mass % or more.

In the perspective of the excellent solubility in water, the content of the component (A) in 100 mass % of the etching liquid is preferably 39.99 mass % or less, preferably 34.95 mass % or less, and preferably 29.92 mass % or less.

### (Component (B))

The compound (B) is at least one compound (B) selected from the group consisting of a thiol compound (B1) and a nonionic surfactant (B2). The etching liquid of the present disclosure contains the component (B), thereby having excellent selective adsorption onto the (100) plane of a silicon crystal.

### Component (B1)

The component (B1) is a thiol compound (B1).

The thiol compound (B1) in the present disclosure may be a compound that decomposes in the etching liquid to produce a thiol compound. Thus, a compound, such as a disulfide compound, that decomposes in the etching liquid to produce a thiol compound also corresponds to the component (B1) according to the present disclosure. That is, the etching liquid of the present disclosure may contain a disulfide compound as the component (B1).

The component (B1) is preferably a compound having a hydrocarbon group and a thiol group and preferably a compound having a hydrophobic hydrocarbon group and a thiol group in the perspective of the excellent adsorption stability on the surface of a silicon crystal.

Examples of the compound (B1) include thioglycerol, thioglycolic acid, ethanolamine thioglycolate, 8-mercaptooctanoic acid, 1-octanethiol, 1-undecanethiol, 1-dodecanethiol, 11-mercapto-1-undecanol, 11-mercaptoundecanoic acid, 16-mercaptohexadecanoic acid, 4,4′-dithiodibutyric acid, bis(2-hydroxyethyl) disulfide, and didodecane disulfide. One of these components (B1) may be used alone, or two or more may be used in combination. Among these components (B1), the component (B1) is preferably thioglycerol, thioglycolic acid, ethanolamine thioglycolate, 1-octanethiol, 1-undecanethiol, 1-dodecanethiol, 11-mercapto-1-undecanol, 11-mercaptoundecanoic acid, or 16-mercaptohexadecanoic acid, preferably thioglycerol, thioglycolic acid, ethanolamine thioglycolate, 11-mercaptoundecanoic acid, or 16-mercaptohexadecanoic acid, and preferably 11-mercaptoundecanoic acid or 16-mercaptohexadecanoic acid in the perspective of the excellent solubility in water.

### Component (B2)

The component (B2) is a nonionic surfactant (B) represented by Formula (1) below:

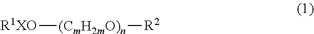

where R¹ is an alkyl group having 7 or more carbons, R² is a hydrogen atom or an alkyl group, X is a single bond or a phenylene group, m is an integer of 1 to 6, and n is from 4 to 25.
R¹ is an alkyl group with 7 or more carbons; in the perspective of the excellent hydrophobic adsorption of the hydrogen terminal to the silicon surface, R¹ is preferably an alkyl group with 7 to 12 carbons.
R² is a hydrogen atom or an alkyl group; in the perspective of the excellent solubility in water, R² is preferably a hydrogen atom or a methyl group and preferably a hydrogen atom.
X is a single bond or a phenylene group; in the perspective of the excellent adsorption stability on the silicon surface, X is preferably a phenylene group.
m is an integer of 1 to 6; in the perspective of the excellent solubility in water, m is preferably from 1 to 3.
n is from 4 to 25; in the perspective of the excellent solubility in water and adsorption stability on the silicon surface, n is preferably from 8 to 25.

Examples of the component (B2) include octylphenol ethoxylate, polyethylene glycol mono-4-nonylphenyl ether, and polyoxyethylene lauryl ether. One of these components (B2) may be used alone, or two or more may be used in combination. Among these components (B2), because of the excellent hydrophobic adsorption of the hydrogen terminal to the silicon surface, the component (B2) is preferably octylphenol ethoxylate, polyethylene glycol mono-4-nonylphenyl ether, or polyoxyethylene lauryl ether, preferably octylphenol ethoxylate or polyethylene glycol mono-4-nonylphenyl ether, and preferably octylphenol ethoxylate.

The content of the component (B) in 100 mass % of the etching liquid is preferably 0.01 mass % or more, preferably 0.05 mass % or more, and preferably 0.08 mass % or more in the perspective of the excellent selective adsorption onto the (100) plane of a silicon crystal. The content of the component (B) in 100 mass % of the etching liquid is preferably 5 mass % or less, preferably 3 mass % or less, and preferably 2 mass % or less in the perspective of the excellent solubility in water.

On the other hand, particularly when the component (B2) is used, its content in 100 mass % of the etching liquid may be 0.0001 mass % or more, 0.0002 mass % or more, or 0.0003 mass % or more in the perspective of the excellent selective adsorption onto the (100) plane of a silicon crystal.

In addition, when the component (B2) is used, its content in 100 mass % of the etching liquid may be 0.001 mass % or less, 0.0009 mass % or less, or 0.0008 mass % or less from the viewpoint of preventing foaming.

### Component (C)

The etching liquid of the present disclosure preferably contains water (component (C)) in addition to the component (A) and the component (B).

In the perspective of the ease of manufacturing the etching liquid and the excellent solubility of the component (A) and the component (B), the content of the component (C) in 100 mass % of the etching liquid is preferably 60 mass % or more, preferably 65 mass % or more, and preferably 70 mass % or more.

In the perspective of the excellent dissolution of silicon, the content of the component (C) in 100 mass % of the etching liquid is preferably 99.5 mass % or less, preferably 98 mass % or less, and preferably 95 mass % or less.

### Additional Component

The etching liquid of the present disclosure may contain an additional component in addition to the component (A), the component (B), and the component (C) as long as the effects of the present disclosure are not impaired; however, the etching liquid may contain no additional component besides the component (A), the component (B), and the component (C).

For example, the content of the additional component in 100 mass % of the etching liquid may be 0.001 mass % or less. In another case, the etching liquid may contain substantially no additional component. The description “the etching liquid may contain substantially no additional component” means that the content of the additional component in 100 mass % of the etching liquid is from 0 mass % to 0.00001 mass %.

Examples of the additional component that may be contained include a chelating agent, a water-miscible solvent, an oxidizing agent, a cationic surfactant, and an anionic surfactant.

The etching liquid of the present disclosure contains a chelating agent, thereby exhibiting a chelating effect for silicon crystal plane-specific adsorption.

Examples of the chelating agent include amine compounds, amino acids, and organic acids. One of these chelating agents may be used alone, or two or more may be used in combination. Among these chelating agents, because of the excellent chelating effect, the chelating agent is preferably an amine compound, an amino acid, or an organic acid, and preferably an amine compound.

Examples of the amine compound include ethylenediamine, 1,3-diaminopropane, 1,4-diaminobutane, ethylenediaminetetraacetic acid, diethylenetriaminepentaacetic acid, triethylenetetraminehexaacetic acid, diethylenetriaminepentakis(methylphosphonic acid), ethylenediamine-N,N′-bis[2-(2-hydroxyphenyl)acetic acid], N,N′-bis(3-aminopropyl)ethylenediamine, N-methyl-1,3-diaminopropane, 2-aminoethanol, N-methyldiethanolamine, and 2-amino-2-methyl-1-propanol. One of these amine compounds may be used alone, or two or more may be used in combination. Among these amine compounds, in the perspective of the excellent chelating effect, the amine compound is preferably ethylenediamine, 1,3-diaminopropane, 1,4-diaminobutane, ethylenediaminetetraacetic acid, diethylenetriaminepentaacetic acid, triethylenetetraminehexaacetic acid, diethylenetriaminepentakis(methylphosphonic acid), ethylenediamine-N,N′-bis[2-(2-hydroxyphenyl)acetic acid], N,N′-bis(3-aminopropyl)ethylenediamine, N-methyl-1,3-diaminopropane, 2-aminoethanol, N-methyldiethanolamine, or 2-amino-2-methyl-1-propanol, and preferably ethylenediamine, 1,3-diaminopropane, 1,4-diaminobutane, ethylenediaminetetraacetic acid, diethylenetriaminepentaacetic acid, triethylenetetraminehexaacetic acid, diethylenetriaminepentakis(methylphosphonic acid), or ethylenediamine-N,N′-bis[2-(2-hydroxyphenyl)acetic acid].

Examples of the amino acid include glycine, arginine, histidine, and N, N-Bis(2-hydroxyethyl)glycine. One of these amino acids may be used alone, or two or more may be used in combination. Among these amino acids, in the perspective of the excellent chelating effect, the amino acid is preferably glycine, arginine, histidine, or (2-dihydroxyethyl)glycine, and preferably (2-dihydroxyethyl)glycine.

Examples of the organic acid include oxalic acid, citric acid, tartaric acid, malic acid, and 2-phosphonobutane-1,2,4-tricarboxylic acid. One of these organic acids may be used alone, or two or more may be used in combination. Among these organic acids, in the perspective of the excellent chelating effect, the organic acid is preferably oxalic acid, citric acid, tartaric acid, malic acid, or 2-phosphonobutane-1,2,4-tricarboxylic acid, and preferably citric acid or 2-phosphonobutane-1,2,4-tricarboxylic acid.

In the etching liquid of the present disclosure containing a chelating agent, in the perspective of the excellent chelating effect, the content of the chelating agent in 100 mass % of the etching liquid is preferably 0.001 mass % or more, preferably 0.005 mass % or more, and preferably 0.01 mass % or more.

In the etching liquid of the present disclosure containing a chelating agent, in the perspective of the excellent solubility in water, the content of the chelating agent in 100 mass % of the etching liquid is preferably 25 mass % or less, preferably 10 mass % or less, and preferably 6 mass % or less.

The etching liquid of the present disclosure contains a water-miscible solvent, thereby exhibiting the effect of allowing a hydrophobic substance, which is not miscible with water, to be mixed with water.

The water-miscible solvent is any solvent with excellent solubility in water; preferably a solvent with a solubility parameter (SP value) of 7.0 (cal/cm³)^{1/2} or more and preferably a solvent with a solubility parameter (SP value) of 9.0 (cal/cm³)^{1/2} or more.

Examples of the water-miscible solvent include polar protic solvents, such as isopropanol, ethylene glycol, propylene glycol, methanol, ethanol, propanol, butanol, glycerol, and 2-(2-aminoethoxyethanol); polar aprotic solvents, such as acetone, dimethyl sulfoxide, N,N-dimethylformamide, N-methylpyrrolidone, and acetonitrile; and non-polar solvents, such as hexane, benzene, toluene, and diethyl ether. One of these water-miscible solvents may be used alone, or two or more may be used in combination.

In the etching liquid of the present disclosure containing a water-miscible solvent, the content of the water-miscible solvent in 100 mass % of the etching liquid is preferably 5 mass % or less and preferably 1 mass % or less; however, the etching liquid preferably contains no water-miscible solvent.

### Mass Ratio of Each Component

The mass ratio of the component (B) to the component (A) (mass of component (B)/mass of component (A), hereinafter described as “(B)/(A)”) in the etching liquid of the present disclosure is preferably from 0.001 to 2, preferably from 0.003 to 2, preferably from 0.005 to 1, and preferably from 0.01 to 0.5 in the perspective of the excellent balance between the dissolution of silicon and the selective adsorption onto the (100) plane of the silicon crystal.

In the etching liquid of the present disclosure containing the component (C), in the perspective of the excellent dissolution of silicon, the mass ratio of the component (A) to the component (C) (mass of component (A)/mass of component (C), hereinafter described as “(A)/(C)”) is preferably from 0.001 to 0.7, preferably from 0.003 to 0.6, and preferably from 0.005 to 0.5.

In the etching liquid of the present disclosure containing the component (C), the mass ratio of the component (B) to the component (C) (mass of component (B)/mass of component (C), hereinafter described as “(B)/(C)”) is preferably from 0.0001 to 0.08, preferably from 0.0005 to 0.03, and preferably from 0.001 to 0.01 in the perspective of the excellent selective adsorption onto the (100) plane of the silicon crystal.

### Method for Manufacturing Etching Liquid

The method for manufacturing the etching liquid of the present disclosure is not particularly limited; the etching liquid can be manufactured by mixing the component (A) and the component (B), and, if necessary, the component (C) and the additional component.

The order of mixing is not particularly limited; all the components may be mixed at once, or some components may be mixed in advance and then the remaining components may be mixed.

### Physical Properties of Etching Liquid

In the perspective of the excellent dissolution of silicon, the pH of the etching liquid of the present disclosure is preferably from 8 to 14, preferably from 9 to 14, and preferably from 10 to 14.

The oxygen concentration of the etching liquid of the present disclosure is preferably 10 mass ppm or less, preferably 5 mass ppm or less, and preferably 1 mass ppm or less in the perspective of suppressing the complete oxidation of silicon.

The etching rate ER₁₁₀ of the (110) plane of a silicon crystal is preferably 1 nm/min or more, preferably 1.5 nm/min or more, and preferably 2 nm/min or more in the perspective of the excellent efficiency of the nano-shape formation in the horizontal direction.

The etching rate ER₁₀₀ of the (100) plane of a silicon crystal is preferably 50 nm/min or less, preferably 30 nm/min or less, and preferably 10 nm/min or less in the perspective of the excellent efficiency of the nano-shape formation in the horizontal direction.

The etching rate ER₁₁₁ of the (111) plane of a silicon crystal is preferably 0.5 nm/min or more, preferably 1.0 nm/min or more, and preferably 1.5 nm/min or more in the perspective of the excellent flat facet formation on the (110) plane of a silicon crystal.

The selective dissolution (ER₁₁₀/ER₁₀₀) of the (110) plane of the silicon crystal relative to the (100) plane of the silicon crystal is 0.5 or more, preferably from 0.6 to 10, preferably from 0.7 to 7, and preferably from 0.8 to 5 in the perspective of the excellent dissolution processability in the horizontal direction of a silicon crystal.

The selective dissolution (ER₁₁₁/ER₁₁₀) of the (111) plane of the silicon crystal relative to the (110) plane of the silicon crystal is preferably 0.2 or more, preferably from 0.3 to 5, and preferably from 0.4 to 3 in the perspective of the excellent flatness of the (110) plane of a silicon crystal.

In the present specification, the etching rate and the selective dissolution are measured by the methods described in the Examples below.

### Etching Target of Etching Liquid

The etching liquid of the present disclosure has excellent selective dissolution of the (110) plane of a silicon crystal relative to the (100) plane of the silicon crystal; thus, the etching liquid is suitable as an etching liquid for silicon dissolution and particularly suitable as an etching liquid for dissolving the (110) plane of a silicon crystal relative to the (100) plane of the silicon crystal.

The silicon to be etched is preferably single crystal silicon because it has a crystal plane orientation. The single crystal silicon can be produced by a known method, and may be produced by cutting a single crystal ingot or by epitaxial growth.

### Etching Method

The etching method of the present disclosure is a method for etching a structure containing silicon using the etching liquid of the present disclosure.

In addition, in another aspect, the etching method of the present disclosure is a method for etching a structure containing silicon, the method including selectively etching the (110) plane of a silicon crystal relative to the (100) plane of the silicon crystal using an etching liquid containing an alkaline compound (A) and at least one compound (B) selected from the group consisting of a thiol compound (B1) and a nonionic surfactant (B2) represented by Formula (2) below:

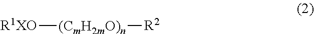

where R¹ is an alkyl group having 1 or more carbons, R² is a hydrogen atom or an alkyl group, X is a single bond or a phenylene group, m is an integer of 1 to 6, and n is from 4 to 25.

The silicon in the structure containing silicon is preferably single crystal silicon because it has a crystal plane orientation. The single crystal silicon can be produced by a known method, and may be produced by cutting a single crystal ingot or by epitaxial growth.

The structure containing silicon may contain a substance besides silicon. Examples of the substances besides silicon include silicon germanium, silicon oxide, silicon nitride, and silicon carbonitride.

As the etching method, a known method can be used; examples include a batch process and a single-wafer process.

In the perspective that the etching rate can be improved, the temperature during etching is preferably 15° C. or higher and preferably 20° C. or higher.

In the perspective of the suppression of damage to a substrate and the provision of etching stability, the temperature during etching is preferably 100° C. or lower and preferably 80° C. or lower.

The temperature during etching corresponds to the temperature of the etching liquid during etching.

### Applications

The etching liquid of the present disclosure has excellent selective dissolution of the (110) plane of a silicon crystal relative to the (100) plane of the silicon crystal; thus, the etching liquid is suitable as an etching liquid for silicon dissolution and particularly suitable as an etching liquid for dissolving the (110) plane of a silicon crystal relative to the (100) plane of the silicon crystal.

Thus, the etching liquid of the present disclosure is suitable for etching a semiconductor device having a structure containing silicon, more suitable for a vertical transistor having a structure containing silicon and a gate-all-around transistor having a structure containing silicon, and particularly suitable for a vertical transistor having a structure containing silicon.

### Method for Manufacturing Semiconductor Device

A method for manufacturing a semiconductor device of the present disclosure includes etching a structure containing silicon using the etching liquid of the present disclosure.

In addition, in another aspect, the method for manufacturing a semiconductor device of the present disclosure is a method for manufacturing a semiconductor device, the method including selectively etching the (110) plane of a silicon crystal relative to the (100) plane of the silicon crystal using an etching liquid containing an alkaline compound (A) and at least one compound (B) selected from the group consisting of a thiol compound (B1) and a nonionic surfactant (B2) represented by Formula (2) below:

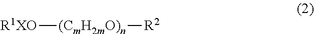

where R¹ is an alkyl group having 1 or more carbons, R² is a hydrogen atom or an alkyl group, X is a single bond or a phenylene group, m is an integer of 1 to 6, and n is from 4 to 25.

### EXAMPLES

Hereinafter, the present disclosure will be described in more detail using examples; however, the present disclosure is not limited to the description of the following examples without departing from the gist of the present disclosure.

### Raw Materials

The following materials were used as raw materials for manufacturing etching liquids in the examples and comparative examples.
Component (A-1): potassium hydroxide
Component (A-2): tetramethylammonium hydroxide
Component (B-1): 11-mercaptoundecanoic acid
Component (B-2): Triton X-100 (trade name, available from Merck Ltd., Japan, octylphenol ethoxylate)
Component (B-3): polyethylene glycol mono-4-nonylphenyl ether (n=about 18)
Component (B-4): diethylene glycol monobutyl ether

### Selective Dissolution of (110) Plane of Silicon Crystal Relative to (100) Plane of Silicon Crystal

A silicon substrate of a silicon crystal with plane orientations of (110) plane and (100) plane was immersed in a 0.5 mass % aqueous hydrofluoric acid solution for 3 minutes and then rinsed with ultrapure water. Thereafter, the back surface of the silicon substrate was masked, and then the silicon substrate was immersed in an etching liquid obtained in each of examples and comparative examples at 60° C. for 10 minutes to 60 minutes. The film thickness of the silicon substrate before and after immersion was measured with a spectral interference-type film thickness meter, and the selective dissolution of the (110) plane of the silicon crystal relative to the (100) plane of the silicon crystal was calculated using equations (1) to (3) below:

$${ER}_{110} [ nm / min ] = ( film thickness [ nm ] of silicon substrate before immersion - film thickness [ nm ] of silicon substrate after immersion ) / ( immersion time [ min ] ) \qquad ( 1 )$$

$${ER}_{100} [ nm / min ] = ( film thickness [ nm ] of silicon substrate before immersion - film thickness [ nm ] of silicon substrate after immersion ) / ( immersion time [ min ] ) \qquad ( 2 )$$

$$Selective dissolution = {ER}_{110} [ nm / min ] / {ER}_{100} [ nm / min ] \qquad ( 3 )$$

### Selective Dissolution of (111) Plane of Silicon Crystal Relative to (110) Plane of Silicon Crystal

A silicon substrate of a silicon crystal with plane orientations of (111) plane and (110) plane was immersed in a 0.5 mass % aqueous hydrofluoric acid solution for 3 minutes and then rinsed with ultrapure water. Thereafter, the back surface of the silicon substrate was masked, and then the silicon substrate was immersed in an etching liquid obtained in each of examples and comparative examples at 60° C. for 10 minutes to 60 minutes. The film thickness of the silicon substrate before and after immersion was measured with a spectral interference-type film thickness meter, and the selective dissolution of the (111) plane of the silicon crystal relative to the (110) plane of the silicon crystal was calculated using equations (4) to (6) below:

$${ER}_{111} [ nm / min ] = ( film thickness [ nm ] of silicon substrate before immersion - film thickness [ nm ] of silicon substrate after immersion ) / ( immersion time [ min ] ) \qquad ( 4 )$$

$${ER}_{110} [ nm / min ] = ( film thickness [ nm ] of silicon substrate before immersion - film thickness [ nm ] of silicon substrate after immersion ) / ( immersion time [ min ] ) \qquad ( 5 )$$

$$Selective dissolution = {ER}_{111} [ nm / min ] / {ER}_{110} [ nm / min ] \qquad ( 6 )$$

### Example 1-1

Components were mixed so that 0.56 mass % of the component (A-1) and 0.10 mass % of the component (B-1) were contained in 100 mass % of an etching liquid with the remainder being water; the mixture was bubbled with nitrogen gas for 5 minutes, thereby obtaining an etching liquid.

Evaluation results of the obtained etching liquid are shown in Table 1.

### Example 1-2

An etching liquid was obtained in the same manner as in Example 1-1 except for changing the types and contents of the components in the etching liquid as shown in Table 1.

Evaluation results of the obtained etching liquid are shown in Table 1.

### Comparative Example 1-1

An etching liquid was obtained in the same manner as in Example 1-1 except for changing the types and contents of the components in the etching liquid as shown in Table 1.

Evaluation results of the obtained etching liquid are shown in Table 1.

### Comparative Example 1-2

An etching liquid was obtained in the same manner as in Example 1-1 except for changing the types and contents of the components in the etching liquid as shown in Table 1.

Evaluation results of the obtained etching liquid are shown in Table 1.

TABLE 1

| | Component (A) | | Component (B) | | | | Selective |
|---|---|---|---|---|---|---|---|
| | | Content | | Content | Etching rate | | dissolution |
| | Type | [mass %] | Type | [mass %] | ER₁₁₀ | ER₁₀₀ | ER₁₁₀/ER₁₀₀ |
| Example 1-1 | (A-1) | 0.56 | (B-1) | 0.1 | 5.3 | 5.8 | 0.91 |
| Example 1-2 | (A-2) | 0.91 | (B-1) | 1.0 | 6.0 | 7.0 | 0.86 |
| Comparative Example 1-1 | (A-1) | 0.56 | — | — | 34.2 | 131.2 | 0.26 |
| Comparative Example 1-2 | (A-2) | 0.91 | — | — | 89.0 | 243.6 | 0.37 |

### Example 2-1

Components were mixed so that 0.56 mass % of the component (A-1) and 0.10 mass % of the component (B-2) were contained in 100 mass % of an etching liquid with the remainder being water, thereby obtaining an etching liquid.

Evaluation results of the obtained etching liquid are shown in Table 2.

### Example 2-2

An etching liquid was obtained in the same manner as in Example 2-1 except for bubbling with nitrogen gas for 5 minutes after mixing the components.

Evaluation results of the obtained etching liquid are shown in Table 2.

### Example 2-3

An etching liquid was obtained in the same manner as in Example 2-1 except for changing the types and contents of the components in the etching liquid as shown in Table 2.

Evaluation results of the obtained etching liquid are shown in Table 2.

### Example 2-4

An etching liquid was obtained in the same manner as in Example 2-2 except for changing the types and contents of the components in the etching liquid as shown in Table 2.

Evaluation results of the obtained etching liquid are shown in Table 2.

### Example 2-5

An etching liquid was obtained in the same manner as in Example 2-1 except for changing the types and contents of the components in the etching liquid as shown in Table 2.

Evaluation results of the obtained etching liquid are shown in Table 2.

### Example 2-6

An etching liquid was obtained in the same manner as in Example 2-2 except for changing the types and contents of the components in the etching liquid as shown in Table 2.

Evaluation results of the obtained etching liquid are shown in Table 2.

### Example 2-7

An etching liquid was obtained in the same manner as in Example 2-1 except for changing the types and contents of the components in the etching liquid as shown in Table 2.

Evaluation results of the obtained etching liquid are shown in Table 2.

### Example 2-8

An etching liquid was obtained in the same manner as in Example 2-2 except for changing the types and contents of the components in the etching liquid as shown in Table 2.

Evaluation results of the obtained etching liquid are shown in Table 2.

### Comparative Example 2-1

An etching liquid was obtained in the same manner as in Example 1 except for changing the types and contents of the components in the etching liquid as shown in Table 2.

Evaluation results of the obtained etching liquid are shown in Table 2.

### Comparative Example 2-2

An etching liquid was obtained in the same manner as in Example 2-2 except for changing the types and contents of the components in the etching liquid as shown in Table 2.

Evaluation results of the obtained etching liquid are shown in Table 2.

TABLE 2

| | | | | | Presence or | | | | | |
|---|---|---|---|---|---|---|---|---|---|---|
| | Component (A) | | Component (B) | | absence of | | | | | |
| | | Content | | Content | nitrogen gas | Etching rate | | | Selective dissolution | |
| | Type | [mass %] | Type | [mass %] | bubbling | ER₁₁₀ | ER₁₀₀ | ER₁₁₁ | ER₁₁₀/ER₁₀₀ | ER₁₁₁/ER₁₁₀ |
| Example 2-1 | (A-1) | 0.56 | (B-2) | 0.10 | Absent | 11.1 | 14.6 | 2.5 | 0.76 | 0.22 |
| Example 2-2 | (A-1) | 0.56 | (B-2) | 0.10 | Present | 3.8 | 3.9 | 1.8 | 0.97 | 0.46 |
| Example 2-3 | (A-2) | 0.91 | (B-3) | 0.10 | Absent | 13.3 | 18.7 | 0.7 | 0.71 | 0.05 |
| Example 2-4 | (A-2) | 0.91 | (B-3) | 0.10 | Present | 1.8 | 2.5 | 0.6 | 0.71 | 0.33 |
| Example 2-5 | (A-1) | 0.56 | (B-4) | 0.10 | Absent | 38.7 | 79.2 | 6.2 | 0.49 | 0.16 |
| Example 2-6 | (A-1) | 0.56 | (B-4) | 0.10 | Present | 19.7 | 42.0 | 2.6 | 0.47 | 0.13 |
| Example 2-7 | (A-2) | 0.91 | (B-4) | 0.10 | Absent | 76.0 | 179.7 | 9.2 | 0.42 | 0.12 |
| Example 2-8 | (A-2) | 0.91 | (B-4) | 0.10 | Present | 28.4 | 65.4 | 4.4 | 0.43 | 0.15 |
| Comparative | (A-1) | 0.56 | — | — | Absent | 131.2 | 394.2 | 4.1 | 0.33 | 0.03 |
| Example 2-1 | | | | | | | | | | |
| Comparative | (A-1) | 0.56 | — | — | Present | 34.2 | 131.2 | 7.3 | 0.26 | 0.21 |
| Example 2-2 | | | | | | | | | | |

As can be seen from Tables 1 and 2, the etching liquids obtained in the examples had excellent selective dissolution of the (110) plane of the silicon crystal relative to the (100) plane of the silicon crystal and also had improved selective dissolution of the (111) plane of the silicon crystal relative to the (110) plane of the silicon crystal.

On the other hand, the etching liquids obtained in the comparative examples had poor selective dissolution of the (110) plane of the silicon crystal relative to the (100) plane of the silicon crystal and poor selective dissolution of the (111) plane of the silicon crystal relative to the (110) plane of the silicon crystal.

### INDUSTRIAL APPLICABILITY

The etching liquid of the present disclosure has excellent selective dissolution of the (110) plane of a silicon crystal relative to the (100) plane of the silicon crystal; thus, the etching liquid is suitable as an etching liquid for silicon dissolution and particularly suitable as an etching liquid for dissolving the (110) plane of a silicon crystal relative to the (100) plane of the silicon crystal.

Thus, the etching liquid of the present disclosure is suitable for etching a semiconductor device having a structure containing silicon, more suitable for a vertical transistor having a structure containing silicon and a gate-all-around transistor having a structure containing silicon, and particularly suitable for a vertical transistor having a structure containing silicon.

1. An etching liquid comprising:
an alkaline compound (A); and
at least one compound (B) selected from the group consisting of a thiol compound (B1) and a nonionic surfactant (B2) represented by Formula (1),
wherein ER₁₁₀/ER₁₀₀≥0.5,
where ER₁₁₀ is an etching rate of a (110) plane of a silicon crystal, and ER₁₀₀ is an etching rate of a (100) plane of the silicon crystal, 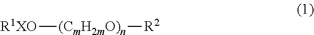
where R¹ is an alkyl group having 7 or more carbons, R² is a hydrogen atom or an alkyl group, X is a single bond or a phenylene group, m is an integer of 1 to 6, and n is from 4 to 25.

2. The etching liquid according to claim 1, wherein the alkaline compound (A) includes at least one compound selected from the group consisting of a quaternary ammonium hydroxide compound, potassium hydroxide, and calcium hydroxide.

3. The etching liquid according to claim 1, wherein the thiol compound (B1) includes a compound having a hydrocarbon group and a thiol group.

4. The etching liquid according to claim 1, wherein the thiol compound (B1) includes at least one compound selected from the group consisting of thioglycerol, thioglycolic acid, ethanolamine thioglycolate, 8-mercaptooctanoic acid, 1-octanethiol, 1-undecanethiol, 1-dodecanethiol, 11-mercapto-1-undecanol, 11-mercaptoundecanoic acid, 16-mercaptohexadecanoic acid, 4,4′-dithiodibutyric acid, bis(2-hydroxyethyl) disulfide, and didodecane disulfide.

5. The etching liquid according to claim 1, wherein X in Formula (1) is a phenylene group.

6. The etching liquid according to claim 1, further comprising water.

7. The etching liquid according to claim 6, wherein a content of water in 100 mass % of the etching liquid is 60 mass % or more.

8. The etching liquid according to claim 1, wherein a content of the alkaline compound (A) in 100 mass % of the etching liquid is from 0.1 mass % to 39.99 mass %.

9. The etching liquid according to claim 1, wherein a content of the compound (B) in 100 mass % of the etching liquid is from 0.01 mass % to 5 mass %.

10. The etching liquid according to claim 1, wherein a mass of the compound (B) relative to a mass of the alkaline compound (A) is from 0.001 to 2.

11. A silicon dissolution solution comprising the etching liquid according to claim 1.

12. The etching liquid according to claim 1, wherein the etching liquid dissolves the (110) plane of the silicon crystal relative to the (100) plane of the silicon crystal.

13. The etching liquid according to claim 1, wherein the silicon is single crystal silicon.

14. An etching method for etching a structure containing silicon using the etching liquid according to claim 1.

15. A method for manufacturing a semiconductor device, the method comprising etching a structure containing silicon using the etching liquid according to claim 1.

16. A method for manufacturing a vertical transistor, the method comprising etching a structure containing silicon using the etching liquid according to claim 1.

17. A method for manufacturing a gate-all-around transistor, the method comprising etching a structure containing silicon using the etching liquid according to claim 1.

18. A method for etching a structure containing silicon, the method comprising selectively etching a (110) plane of a silicon crystal relative to a (100) plane of the silicon crystal using an etching liquid containing an alkaline compound (A) and at least one compound (B) selected from the group consisting of a thiol compound (B1) and a nonionic surfactant (B2) represented by Formula (2): 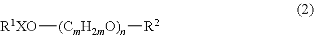
where R¹ is an alkyl group having 1 or more carbons, R² is a hydrogen atom or an alkyl group, X is a single bond or a phenylene group, m is an integer of 1 to 6, and n is from 4 to 25.

19. A method for manufacturing a semiconductor device, the method comprising selectively etching a (110) plane of a silicon crystal relative to a (100) plane of the silicon crystal using an etching liquid containing an alkaline compound (A) and at least one compound (B) selected from the group consisting of a thiol compound (B1) and a nonionic surfactant (B2) represented by Formula (2): 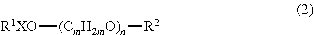
where R¹ is an alkyl group having 1 or more carbons, R² is a hydrogen atom or an alkyl group, X is a single bond or a phenylene group, m is an integer of 1 to 6, and n is from 4 to 25.
